(19) United States
(12) Patent Application Publication
(10) Pub. No.: US 2026/0293657 A1
(43) Pub. Date: Sep. 24, 2026

(54) DEVICES WITH AIRGAP

(71) Applicant: GlobalFoundries Singapore Pte. Ltd., Singapore (SG)

(72) Inventors: Dau Fatt Lim, Singapore (SG); Wanbing Yi, Singapore (SG)

(21) Appl. No.: 19/085,077

(22) Filed: Mar. 20, 2025

(51) Int. Cl. H10W 20/46; H10W 20/00; H10W 20/47

(52) U.S. Cl. CPC H10W 20/46; H10W 20/072; H10W 20/47

(57) ABSTRACT

The present disclosure relates to semiconductor structures and, more particularly, to devices with an airgap and methods of manufacture. The device includes: at least one gate structure over a semiconductor substrate; a first insulator material over the at least one gate structure; at least one upper wiring structure above the at least one gate structure and the first insulator material; and an inverted T-shaped airgap within the first insulator material and between the at least one gate structure and the at least one upper wiring structure.

### BACKGROUND

The present disclosure relates to semiconductor structures and, more particularly, to devices with an airgap and methods of manufacture.

A switching device is a solid-state switch made of semiconductor material that can be used to turn electrical signals and power on or off. In this way, for example, example, switching devices in semiconductors are electronic devices that control the flow of current or power. The switching devices are used in RF devices, solar power, and other applications, such as switch-mode power supplies. Examples of such switching devices may include transistors that can amplify or switch electrical signals.

### SUMMARY

In an aspect of the disclosure, a structure comprises: at least one gate structure over a semiconductor substrate; a first insulator material over the at least one gate structure; at least one upper wiring structure above the at least one gate structure and the first insulator material; and an inverted T-shaped airgap within the first insulator material and between the at least one gate structure and the at least one upper wiring structure.

In an aspect of the disclosure, a structure comprises: at least one gate structure; a first interconnect structure extending from a first diffusion region on a first side of the at least one gate structure; a second interconnect structure extending from a second diffusion region on a second side of the at least one gate structure; a first wiring structure connecting to the first interconnect structure; a second wiring structure connecting to the second interconnect structure; and an airgap comprising a horizontal portion and a vertical portion extending from the horizontal portion, the horizontal portion being between the at least one gate structure and the first and second wiring structures and the vertical portion being between the first and second wiring structures and between the first and second interconnect structures.

In an aspect of the disclosure, a method comprises: forming at least one gate structure over a semiconductor substrate; forming a first insulator material over the at least one gate structure; forming at least one upper wiring structure above the at least one gate structure and the first insulator material; and forming an inverted T-shaped airgap within the first insulator material and between the at least one gate structure and the at least one upper wiring structure.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows a structure in accordance with additional aspects of the present disclosure.

FIG. 3 shows another structure in accordance with additional aspects of the present disclosure.

FIGS. 4A-4D show fabrication processes to manufacture the structure of FIG. 1 in accordance with aspects of the present disclosure.

FIGS. 5A-5C show fabrication processes to manufacture the structure of FIG. 3 in accordance with aspects of the present disclosure.

### DETAILED DESCRIPTION

The present disclosure relates to semiconductor structures and, more particularly, to devices with an airgap and methods of manufacture. More specifically, the airgap may comprise an inverted T-shaped profile located between a gate structure of the devices and a wiring structure (e.g., wiring and interconnect structures). Advantageously, the inverted T-shaped airgap reduces metal to gate capacitance to improve RF switch performance. Also, the inverted T-shaped airgap provides a Coff reduction in both planar and in 3D stacking devices. The inverted T-shaped airgap also provides better process control for etch and bulk formation, in addition to high flexibility of horizontal patterning to support different pitch switch devices and depths.

More specifically, the switch devices with the airgap can achieve high isolation when in the “off” state, essentially acting as a very effective switch with minimal resistance when turned “on”. For example, the air gap acts as a very high-impedance insulator when the switch is off, preventing current flow. The switches can thus be used in high-frequency applications where minimal signal loss is crucial.

The switch devices of the present disclosure can be manufactured in a number of ways using a number of different tools. In general, though, the methodologies and tools are used to form structures with dimensions in the micrometer and nanometer scale. The methodologies, i.e., technologies, employed to manufacture the switch devices of the present disclosure have been adopted from integrated circuit (IC) technology. For example, the structures are built on wafers and are realized in films of material patterned by photolithographic processes on the top of a wafer. In particular, the fabrication of the switch devices uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

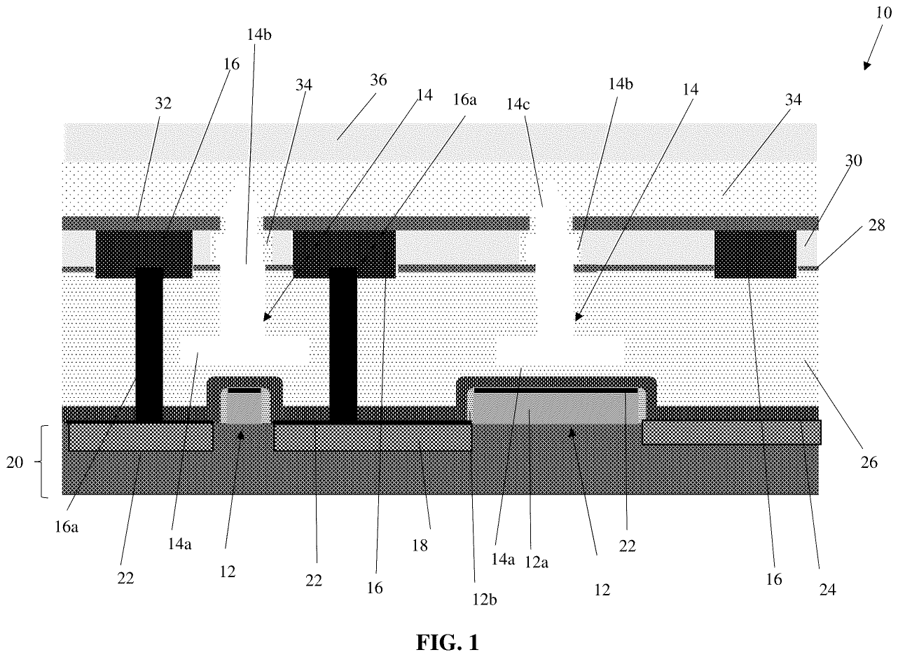

FIG. 1 shows a structure and respective fabrication processes in accordance with aspects of the present disclosure. More specifically, the structure 10 of FIG. 1 includes one or more gate structures 12, e.g., switching devices, and an airgap 14. The airgap 14 may be located over each of the one or more gate structures 12 and, more specifically, between the one or more gate structures 12 and an upper wiring structure 16. The airgap 14 may comprise an inverted T-shaped profile comprising a horizontal portion 14a and a vertical portion 14b. The vertical portion 14b of the airgap 14 may be between interconnect structures 16a extending from source/drain regions, e.g., diffusion regions, 18 of the gate structures 12 and wiring structures 16 on at least a first wiring level. The length of the vertical portion 14b may be tunable, e.g., extend to different metal layers.

More specifically, the structure 10 may comprise a plurality of gate structures 12 provided on a semiconductor substrate 20. The semiconductor substrate 20 may be a bulk semiconductor or semiconductor on insulator (SOI) technology. In either scenario, the semiconductor substrate 20 may be composed of any suitable material including, but not limited to, Si, SiGe, SiGeC, SiC, GaAs, InAs, InP, and other III/V or II/VI compound semiconductors. In further embodiments, the semiconductor substrate 20 may comprise any suitable single crystallographic orientation (e.g., a (100), (110), (111), or (001) crystallographic orientation). In the SOI technology, from bottom to top, a handle substrate, a buried insulator layer (i.e., substrate) and a top semiconductor layer are provided, with at least the top semiconductor layer comprising the materials and crystallographic orientation described herein.

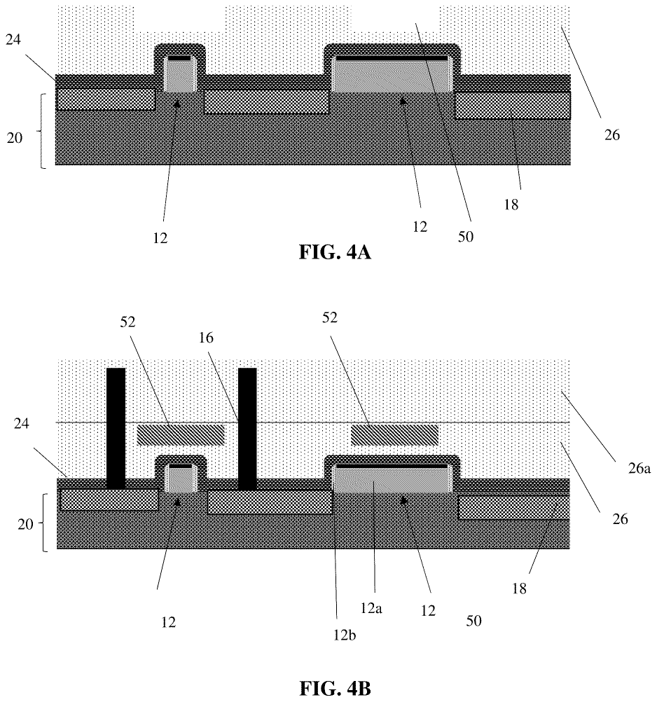

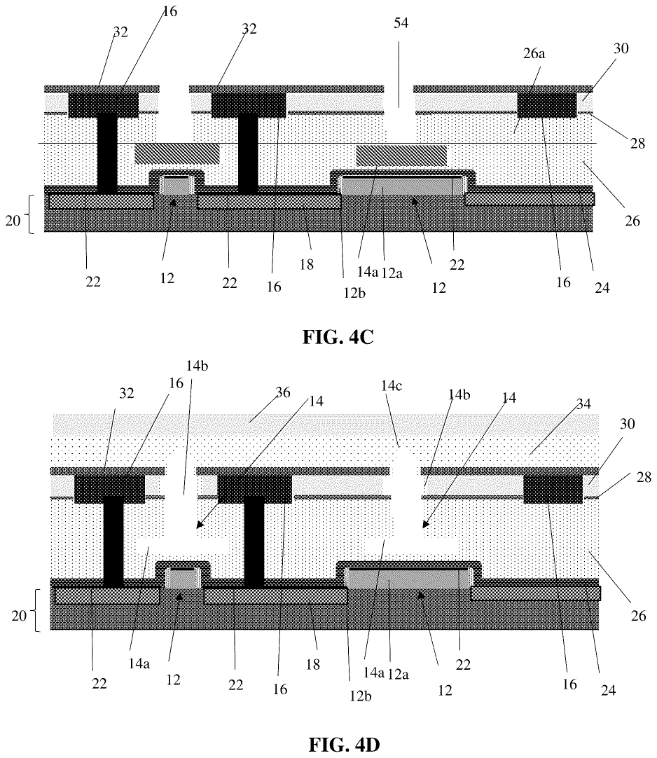

The plurality of gate structures 12 may be provided on the semiconductor substrate 20. The gate structures 12 include gate dielectric material and a gate electrode both of which are represented at reference numeral 12a. Sidewall spacers 12b may be provided on a sidewall of the gate dielectric material and the gate electrode 12a. The gate dielectric material may be any low-k dielectric material, e.g., oxide base materials, or high-k gate dielectric material, e.g., hafnium oxide based materials, aluminum oxide base material, etc. The gate electrode may be polysilicon material. The sidewall spacers 12b may be an oxide material or nitride material or combination thereof. Although not critical to the understanding of the present disclosure, the gate structures 12 can be fabricated using conventional CMOS processes, e.g., standard CMOS or replacement gate processes as described with respect to FIG. 4A.

Source/drain regions 18 are provided adjacent to the gate structures 12. The source/drain regions 18 may be formed by introducing a concentration of dopant in the semiconductor substrate 20 as also described with respect to FIG. 4A. Depending on the device characteristics, a p-type dopant, e.g., Boron (B), or n-type dopant, e.g., Arsenic (As), Phosphorus (P) and Antimony (Sb), etc., may be used to form the source/drain regions 18.

Silicide contacts 22 may be formed over the source/drain regions 18 and the gate structures 12. The silicide contacts 22 may be formed by a silicide process that begins with deposition of a thin transition metal layer, e.g., nickel, cobalt or titanium, over fully formed and patterned semiconductor devices (e.g., doped or ion implanted source/drain regions 18 and respective gate structures 12). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts 22 in the active regions of the device. It should be understood by those of skill in the art that silicide contacts will not be required on the devices, when a gate structure is composed of a metal material.

An insulator material 24 may be formed over the gate structures 12, silicide contacts 22 and any exposed semiconductor material 20. In embodiments, the insulator material 24 may comprise nitride material that is deposited by a conventional deposition process, e.g., chemical vapor deposition (CVD). A plurality of insulator materials 26, 28, 30, 32, 34, 36 are formed over the insulator material 24. By way of illustrative, non-limiting examples, the insulator material 26 may be interlevel dielectric material, e.g., oxide. The insulator material 28 may be carbon doped silicon nitride. The insulator material 30 may be oxide material, e.g., fluoride doped oxide and, more specifically, fluoride doped TEOS. The insulator material 32 may be carbon doped silicon nitride. The insulator material 34 may be oxide material and the insulator material 36 may be oxide material, e.g., fluoride doped oxide and, more specifically, fluoride doped TEOS. It should be understood that the unless otherwise specified, the insulator materials may be formed by conventional deposition processes, e.g., CVD. Also, the insulator materials are provided as exemplary embodiments such that other insulator materials or combinations thereof can be implemented with the present disclosure.

Still referring to FIG. 1, interconnect structures 16a extend from the silicide contacts 22 on the source/drain regions 18 of the gate structures 12. In embodiments, the interconnect structures 16a extend through the insulator materials 24, 26 to respective wiring structures 16 on a first wiring layer. As described further herein, the interconnect structures 16a and the wiring structures 16 may be formed by conventional lithography, etching and deposition processes, with the insulator layer 32 provided over the wiring structures 16. The interconnect structures 16a may be copper, aluminum or other appropriate conductive metals used in the fabrication of semiconductor devices as is known in the art. The wiring structures 16 may be, for example, aluminum, titanium, or tungsten with an appropriate liner, e.g., TaN or TiN as is known in the art.

FIG. 1 further shows the airgap 14 between the wiring structures 16, interconnect structures 16a and the gate structures 12. The airgap 14 may be isolated from the gate structures 12 by the insulator materials 24, 26. In embodiments, the airgap 14 comprises an inverter T-shaped profile with a horizontal portion 14a and a vertical portion 14b. The horizontal portion 14a of the airgap 14 may be provided between the gate structures 12 and the wiring structures 16. The horizontal portion 14a is thus positioned to reduce metal to gate capacitance to improve RF switch performance. Also, the inverted T-shaped airgap 14 provides a Coff reduction in both planar and in 3D stacking devices.

The vertical portion 14b of the airgap 14 may be located between adjacent wiring structures 16 and interconnect structures 16a. In embodiments, the vertical portion 14b of the airgap 14 may extend into the insulator material 34, above the wiring structures 16; although other dimensions are also contemplated herein. In embodiments, a pinch off 14c may form over the vertical portion 14b of the airgap 14 due to the deposition process of the insulator material 34. The top portion, e.g., portion extending through the insulator materials 30, 32 of the vertical portion 14b of the airgap 14 may also be lined with the insulator material 34.

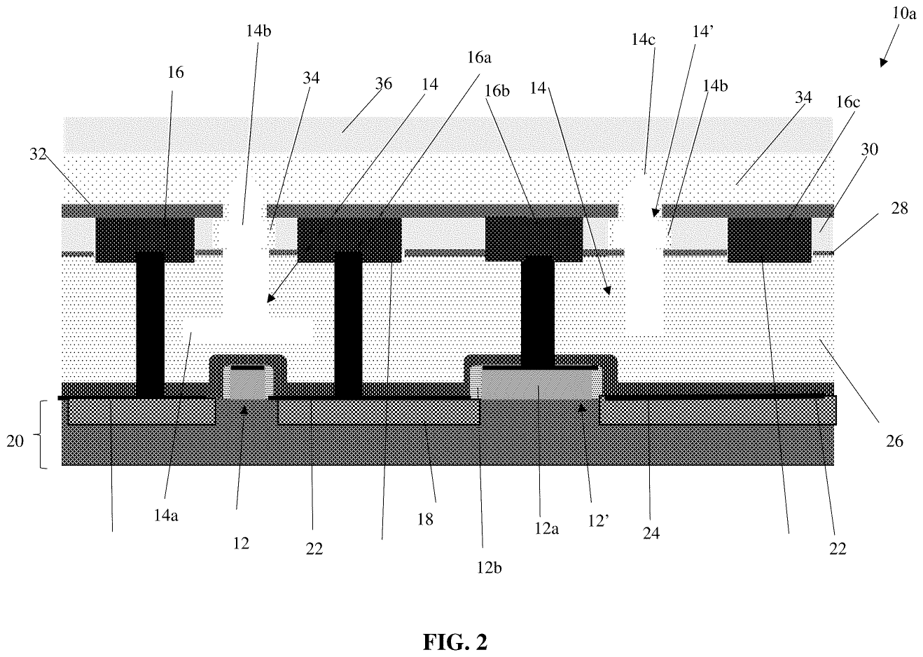

FIG. 2 shows a structure in accordance with additional aspects of the present disclosure. In the structure 10a of FIG. 2, an airgap 14′ is provided between the wiring structures 16b, 16c. In this embodiment, the airgap 14′ includes only the vertical portion 14b (e.g., devoid of the horizontal portion) which extends between and, in embodiments, above, adjacent to and below the wiring structures 16b, 16. As already noted herein, the vertical portion 14b of the airgap 14′ may be tunable to different dimensions, e.g., lengths. The airgap 14, on the other hand, includes both the horizontal portion 14a and vertical portion 14b and may be provided between adjacent gate structures 12, 12′ (similar to that described with respect to the structure 10 of FIG. 1). This cross-sectional view also shows the interconnect structures 16a and wiring structures 16 extending to and contacting the silicide contact 22 on the gate electrode 12a of the gate structure 12′. The remaining features of the structure 10b are similar to the structure 10 of FIG. 1 such that no further explanation is required for a complete understanding of the present disclosure.

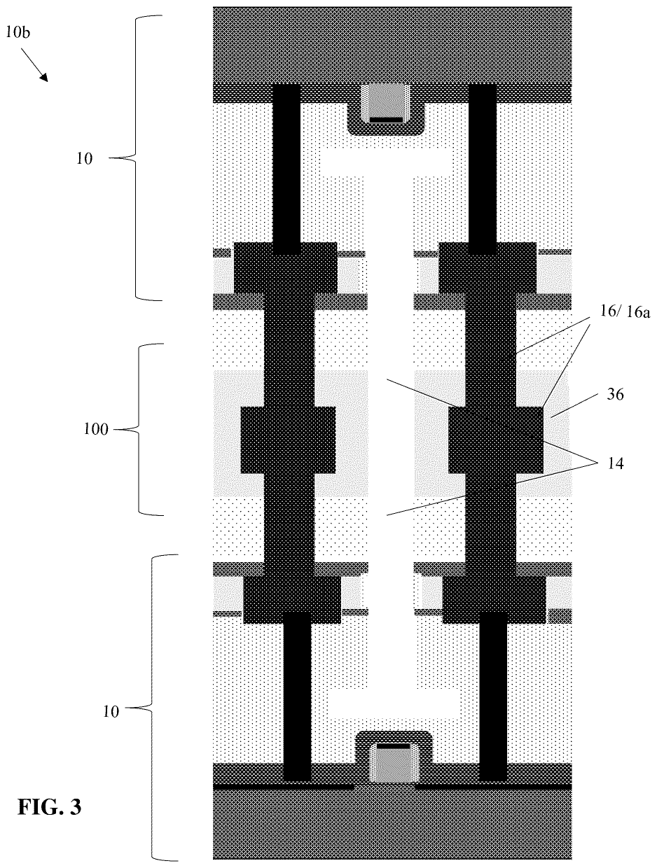

FIG. 3 shows another structure in accordance with additional aspects of the present disclosure. In the structure 10b of FIG. 3, the structures 10 shown in FIG. 1 or other similar structures with the inverted T-shaped profile airgap 14 are bonded together at, for example, interface 100. In this configuration, the inverted T-shaped profile airgap 14 is aligned and connects together to form a single airgap extending between the bonded structures. In embodiments, the interface 100 may comprise the insulator material 34 bonded together, with the vertical portions 14b of the inverted T-shaped profile airgap 14 extended through the insulator material 36 and connecting together within the interface 100.

FIGS. 4A-4D show fabrication processes to manufacture the structure 10 of FIG. 1 in accordance with aspects of the present disclosure. It should be understood by those of skill in the art that similar fabrication processes may be used to manufacture the structure 10a of FIG. 2.

In FIG. 4A, the gate structures 12 may be formed over the semiconductor substrate 20. Although not critical to the understanding of the present disclosure, the gate structures 12 can be fabricated using conventional CMOS processes, e.g., standard CMOS or replacement gate processes. In the standard CMOS processing, for example, a gate dielectric material and polysilicon material 12a are formed, e.g., deposited, on the semiconductor substrate 20, followed by a conventional patterning process, e.g., lithography and etching processes. An insulator material such as nitride or oxide can be deposited on the patterned materials, followed by an anisotropic etching process to form the sidewall spacers 12b.

The source/drain regions 18 are formed adjacent to the gate structures 12 and can be fabricated by an ion implantation process or, if raised source/drain structures are required, by an epitaxial growth process. In an ion implantation process, the source/drain regions 18 may be formed by introducing a concentration of dopant in the semiconductor substrate 20. In the ion implantation process, patterned implantation masks may be used to define selected areas exposed for the implantations. The implantation mask may include a layer of a light-sensitive material, such as an organic photoresist, applied by a spin coating process, pre-baked, exposed to light projected through a photomask, baked after exposure, and developed with a chemical developer. The implantation masks have a thickness and stopping power sufficient to block masked areas against receiving a dose of the implanted ions. Depending on the device characteristics, a p-type dopant, e.g., Boron (B), or n-type dopant, e.g., Arsenic (As), Phosphorus (P) and Antimony (Sb), etc., may be used to form the source/drain regions 18.

For raised source/drain regions 18, examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used. A dopant (n-type or p-type, as defined below) is typically added to the precursor gas or gas mixture.

The insulator materials 24, 26 may be formed over the source/drain regions 18 and the gate structures 12 by a conventional deposition process as is known in the art, e.g., CVD. The insulator materials 24, 26 may be nitride and oxide, respectively, although other materials are also contemplated herein.

A trench 50 may be formed in the insulator material 26, above and in alignment with the gate structures 12. The trench 50 can be formed by conventional lithography and etching methods known to those of skill in the art. The width of the trench 50 is tunable, depending on the dimensions of the gate structures 12 and the distance between the interconnect structures 16a. For example, a resist formed over the insulator material 26 is exposed to energy (light) and developed utilizing a conventional resist developer to form a pattern (opening). An etching process with a selective chemistry, e.g., reactive ion etching (RIE), will be used to transfer the pattern to form one or more trenches 50 in the insulator material 26 through the openings of the resist. The resist may be removed by a conventional oxygen ashing process or other known stripants.

In FIG. 4B, a material 52 with an etch selectivity to the insulator material 26 may be deposited in the trench 50. The material 52 may be a nitride material which has an etch selectivity to the insulator material 26, e.g., oxide. The material 52 can be deposited by any conventional deposition processes, e.g., CVD processes. Any residual material on the surface of the insulator material 26 can be removed by conventional chemical mechanical polishing (CMP) processes. Additional insulator material 26a may be deposited over the material 52. In embodiments, the insulator material 26a may be an interlevel dielectric material similar to the insulator material 26 and with an etch selectivity to the material 52. The interconnect structures 16a may be formed through the insulator materials 26, 26a using conventional lithography, etching and deposition processes as described herein.

In FIG. 4C, the insulator materials 28, 30, 32 may be deposited over the insulator material 26a by conventional deposition methods as already described herein. The wiring structures 16 may be formed within the insulator materials 28, 30, 32 or combinations thereof such as insulator material 28, or insulator materials 28, 30, etc., connecting to the interconnect structures 16a. The wiring structures 16 may be formed by conventional lithography, etching and deposition processes as described herein. A vertical trench 54 may be formed through the insulator materials 26a, 28, 30, 32, which exposes a top surface of the material 52. In embodiments, the trench 54 may be used to form the vertical portion of the airgap 14. The trench 54 may undergo a cleaning process, e.g., dHF clean.

In FIG. 4D, the material 52 may be removed by using a selective etch process to the insulator materials 26, 26a. In this way, the horizontal portion 14a of the airgap 14 can be formed in the structure. The insulator material 34 may be deposited over the insulator material 32 and the trench 54, sealing the airgap 14. It should be recognized that the trench 54 will form the pinch off 14c on an upper portion of the vertical portion 14b of the airgap 14. In this way, the inverted T-shaped profile of the airgap 14 can be formed within the structure.

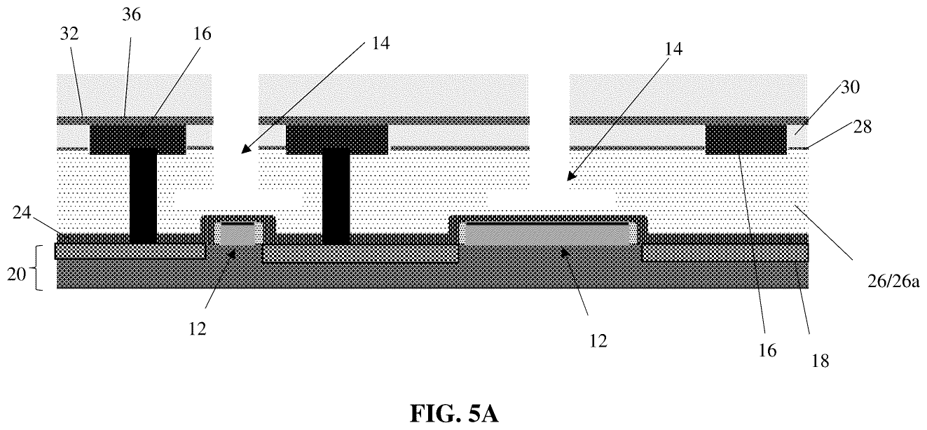

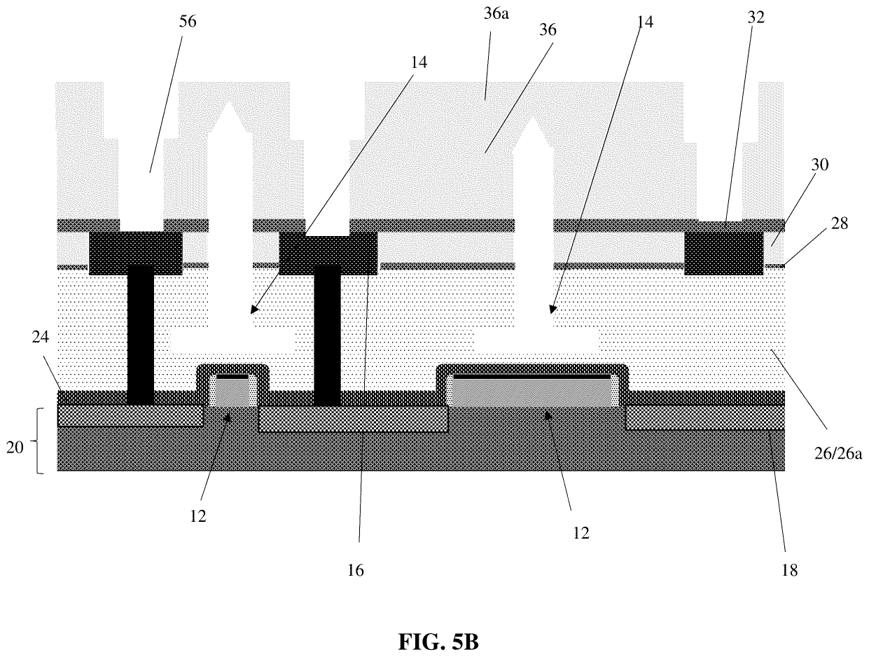

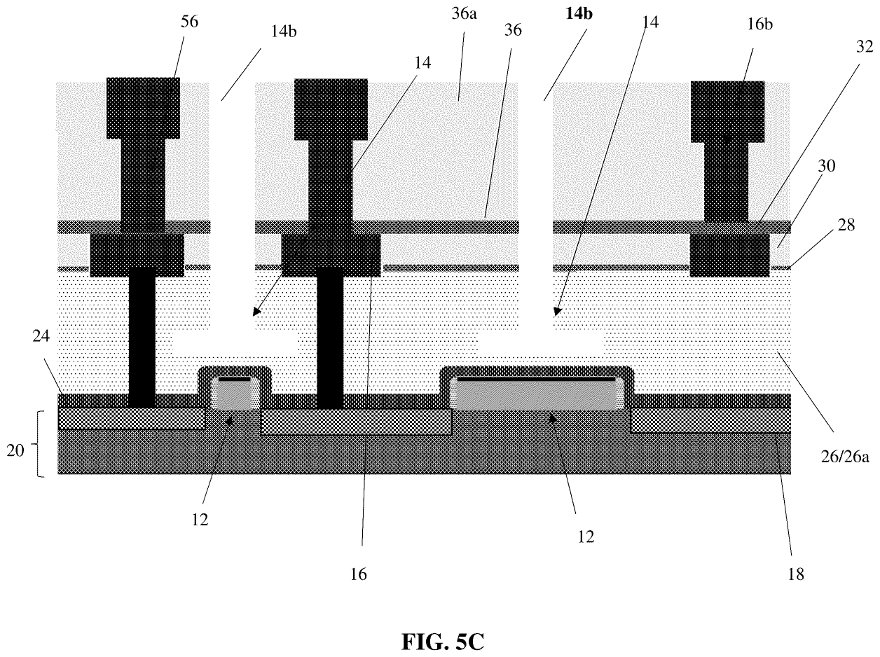

FIGS. 5A-5C show fabrication processes to manufacture the structure of FIG. 3 in accordance with aspects of the present disclosure. FIG. 5A starts from the structure shown in FIG. 4B, with the exception that the insulator materials 28, 30, 32, 36 are formed over the insulator material 26a. The trench 54 may be formed through the insulator materials 28, 30, 32, 36, exposing the material 52. The insulator materials 28, 30, 32, 36, the material 52 and the remaining structures shown in FIG. 5A may be formed as already described herein.

In FIG. 5B, the trench 54 is sealed by forming additional insulator material 36a over the insulator material 36. In embodiments, the insulator material 36a may be the same material as the insulator material 36, which forms the interface 100 in FIG. 3, for example. As an example, the insulator materials 36, 36a may be oxide material, e.g., fluoride doped oxide and, more specifically, fluoride doped TEOS. The insulator material 36a seals the airgap 14 by forming a pinch off 14c.

Still referring to FIG. 5B, an etching process may be performed in the insulator materials 36, 36a to form trench structures 56 over the wiring structures 16. In this way, the upper surface of the wiring structures 16 will be exposed though the trench structure 56. In embodiments, the trench structure 56 may be a dual trench structure formed by conventional lithography processes including a two single damascene processes or a dual damascene process as is known in the art. In the either process, the trench structures 56 will include a lower, wider section and an upper, narrower section.

In FIG. 5C, the trench structures 56 are filled with conductive material 16b. For example, the trench structures can be filled with conductive material for an interconnect structure connecting to the wiring structure 16 and conductive material for an upper wiring structure as already described herein. The conductive material can be deposited using any conventional deposition methods, e.g., CVD. Any excessive material on the insulator material 36a may be subjected to a planarization process, e.g., chemical mechanical polishing (CMP). The CMP process will also expose the vertical portion 14b of the airgap structure 14. The open airgap structure can be subjected to a cleaning process, e.g., dHF. Two of the same structures can then be bonded together by, for example, flipping over one structure, aligning the wring structures 16b and vertical portion 14b of the airgaps and followed by a bonding process.

The insulator materials 36a may be bonded together, for example, by a direct bonding process where two oxide-coated surfaces are brought into close contact and heated at a specific temperature to facilitate a chemical reaction, effectively merging the oxide layers at the interface 100; although other processes are also contemplated herein. The wiring structures 16 and interconnect structures 16a may also be aligned and connect together at the interface 100, e.g., insulator material 36.

The switch devices can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
at least one gate structure over a semiconductor substrate;
a first insulator material over the at least one gate structure;
at least one upper wiring structure above the at least one gate structure and the first insulator material; and
an inverted T-shaped airgap within the first insulator material and between the at least one gate structure and the at least one upper wiring structure.

2. The structure of claim 1, wherein the inverted T-shaped airgap comprises a horizontal portion and a vertical portion within the first insulator material.

3. The structure of claim 2, wherein the horizontal portion is located between the at least one gate structure and the at least one upper wiring structure.

4. The structure of claim 2, further comprising a source region connecting to a first interconnect structure and a drain region connecting to a second interconnect structure, the vertical portion of the inverted T-shaped airgap being between the first interconnect structure and the second interconnect structure.

5. The structure of claim 4, wherein the at least one upper wiring structure comprises a first wiring structure and a second wiring structure connecting to first interconnect structure and the second interconnect structure, respectively, and the vertical portion of the inverted T-shaped airgap additionally extends between the first wiring structure and the second wiring structure.

6. The structure of claim 5, wherein the first wiring structure and the second wiring structure are within additional insulator material above the insulator material, and the vertical portion of the inverted T-shaped airgap extends into the additional insulator material.

7. The structure of claim 2, wherein the vertical portion of the inverted T-shaped airgap is tunable.

8. The structure of claim 1, further comprising an airgap structure with a vertical portion, only, and which adjacent to the at least one gate structure.

9. The structure of claim 8, further comprising an interconnect structure that extends to a diffusion region of the at least one gate structure, wherein the inverted T-shaped airgap is on a first side of the interconnect structure and the airgap structure is on an opposing side of interconnect structure.

10. The structure of claim 1, further comprising a second insulator material below the first insulator material, the second insulator material being different than the first insulator material and being located between the inverted T-shaped airgap and the at least one gate structure.

11. The structure of claim 10, wherein the first insulator material is between the inverted T-shaped airgap and the second insulator material.

12. The structure of claim 1, wherein the structure comprises a hybrid device comprising a first switch device connected to a second switch device at an interface, wherein:
each of the first switch device and the second switch device comprises the at least one gate structure, the at least one upper wiring structure, the insulator material and the inverted T-shaped airgap; and
the inverted T-shaped airgap of the first switch device and the inverted T-shaped airgap of the second switch device are aligned together to form a single airgap feature with a common vertical portion and separate horizontal portions that are located between the wiring structure and at least one gate structure of the first switch device and the second switch device.

13. A structure comprising:
at least one gate structure;
a first interconnect structure extending from a first diffusion region on a first side of the at least one gate structure;
a second interconnect structure extending from a second diffusion region on a second side of the at least one gate structure;
a first wiring structure connecting to the first interconnect structure;
a second wiring structure connecting to the second interconnect structure; and
an airgap comprising a horizontal portion and a vertical portion extending from the horizontal portion, the horizontal portion being between the at least one gate structure and the first and second wiring structures and the vertical portion being between the first and second wiring structures and adjacent the first interconnect structure.

14. The structure of claim 13, wherein the airgap is between the first and second interconnect structures.

15. The structure of claim 14, further comprising a second airgap, the second airgap comprising a horizontal portion and a vertical portion extending from the horizontal portion, the horizontal portion being between the at least one gate structure and the first and second wiring structures and the vertical portion being between the first and second wiring structures and adjacent the first interconnect structure.

16. The structure of claim 14, further comprising a second airgap, the second airgap comprising a vertical portion between the first and second wiring structures and extending within insulator material above the at least one gate structure.

17. The structure of claim 13, wherein the airgap comprises an inverted T-shaped profile.

18. The structure of claim 13, wherein the structure comprises a first switch device connected to a second switch device, wherein:
each of the first switch device and the second switch device comprises the at least one gate structure, the first wiring structure, the second wiring structure and the airgap; and
the airgap of the first switch device and the second switch device are aligned together to form a single airgap feature with a common vertical portion and separate horizontal portions.

19. The structure of claim 13, wherein the horizontal portion and the vertical portion of the airgap are provided within a same insulator material, above the gate structure and below the first and second wiring structures.

20. A method comprising:
forming at least one gate structure over a semiconductor substrate;
forming a first insulator material over the at least one gate structure;
forming at least one upper wiring structure above the at least one gate structure and the first insulator material; and
forming an inverted T-shaped airgap within the first insulator material and between the at least one gate structure and the at least one upper wiring structure.
